(19) United States
(12) Patent Application Publication
(10) Pub. No.: US 2007/0133280 A1
(43) Pub. Date: Jun. 14, 2007

(54) Semiconductor integrated circuit apparatus and electronic system

(75) Inventors: Masashi Oshiba, Tachikawa (JP); Hiroshi Kishi, Akishima (JP); Yoshiaki Sato, Kodaira (JP); Yoko Yamaki, Kodaira (JP); Kentaro Yamakawa, Fuchu (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 10/583,778

(22) PCT Filed: Oct. 8, 2004
(86) PCT No.: PCT/JP04/14939

§ 371 Date: Jun. 21, 2006

(51) Int. Cl. G11C 16/04

(52) U.S. Cl. 365/185.04

(57) ABSTRACT

A flash memory is provided with a protect area PA in which reading of a specific block is prohibited. A RAM to be used as a work area of a program is provided with a protect area PA1 in which reading of a specific block is prohibited. A bus state controller 3 compares a value of a program counter and a value of an address signal to prohibit reading in areas other than the protect area PA in the flash memory and to prohibit reading of data of protect area PA1 in the RAM other than reading from the protect area PA of the flash memory. For instance, when a user reads data of the protect area PA from a user access area to which the user can access, senseless data such as H'FFFF are output from the bus state controller 3 via a data bus.

### TECHNICAL FIELD

The present invention relates to a data protection technology in a nonvolatile semiconductor memory and, particularly, to a technology effectively applied to prevention of copying and rewriting of a program in a semiconductor integrated circuit apparatus having the internal nonvolatile semiconductor memory therein.

### BACKGROUND ART

In recent years, for the purposes of accelerating developments and improvements of electronic appliances, there has been an increasing demand for a semiconductor integrated circuit apparatus having an integrated nonvolatile semiconductor memory therein, i.e. a microcomputer with a built-in flash memory, in which a control program and control data are easily rewritten.

Some of such microcomputers with built-in flash memory have a protect function for prohibiting rewriting of an application program and the like stored in the flash memory for the purpose of security protection.

As the protection function for data and program stored in the nonvolatile semiconductor memory, there has been proposed a technology wherein a programmer stores a program in a protection block set by the programmer in EPROM (Erasable Programmable Read only Memory) and then sets a specified bit of a protection register in the EPROM to prohibit reading/writing from outside the protection area (see Patent Literature 1, for example).

Patent Literature 1: JP-A-2000-76133

### DISCLOSURE OF THE INVENTION

### PROBLEMS THAT THE INVENTION IS TO SOLVE

The inventor of this invention has found that the protect technologies in microcomputer with built-in flash memory have the following problems.

In the case where a protect function of a flash memory is enabled, it is advantageous that programs and the like cannot be read by a third person, but, due to the protection on a memory block (block) of the flash memory, user data cannot be updated.

Also, since it is possible to easily rewrite an application program by starting a boot mode with the flash memory being mounted on a printed circuit board of an electronic system, there is a risk of reading/rewriting of the application program by third party.

Further, even when the flash memory is protected, there is a risk that contents of an application program can be guessed when contents of a RAM (Random Access Memory) which is used as a work area of a CPU provided in a microcomputer are read out and instructions are analyzed.

An object of this invention is to provide a technology for preventing without fail illegal copying or alteration of a program by a third party by prohibiting reading in a specific memory block of a nonvolatile semiconductor memory.

The above and other objects and novel characteristics of this invention will become apparent from the following description and accompanying drawings.

### MEANS FOR SOLVING THE PROBLEMS

Summary of a representative one of invention disclosed in this patent application is as follows.

This invention provides a semiconductor integrated circuit apparatus comprising: a nonvolatile storage provided with a memory array unit having a plurality of nonvolatile memory cells and a control unit for controlling write operation of storing information in the nonvolatile memory cells, read operation of reading out the information stored in the nonvolatile memory cells, and erase operation of erasing the information stored in the nonvolatile memory cells; a volatile storage to be used as a work area of a program stored in the nonvolatile storage; a central processing unit capable of executing a predetermined processing and giving instructions to the nonvolatile storage; and a protect operation control unit for controlling the nonvolatile storage and the read operation of the nonvolatile storage, wherein the memory array unit has a first protect memory area in which reading and writing of information stored are prohibited under the control of the protect operation control unit; the volatile storage has a second protect memory area in which reading from an area other than the first protect memory area of the memory array unit is prohibited under the control of the protect operation control unit; and the second protect memory area of the volatile storage is used as a work area of a program stored in the first protect memory area of the nonvolatile storage.

Also, this invention provides a semiconductor integrated circuit apparatus comprising a nonvolatile storage provided with a memory array unit having a plurality of nonvolatile memory cells and a control unit for controlling write operation of storing information in the nonvolatile memory cells, read operation of reading out the information stored in the nonvolatile memory cells, and erase operation of erasing the information stored in the nonvolatile memory cells; a volatile storage; a central processing unit capable of executing a predetermined processing and giving instructions to the nonvolatile storage; and a protect operation control unit for controlling the nonvolatile storage and the read operation of the nonvolatile storage, wherein the memory array unit has a first protect memory area in which reading and writing of information stored are prohibited under the control of the protect operation control unit; and the volatile storage has a second protect memory area in which reading and writing from an area other than the first protect memory area of the memory array unit are prohibited under the control of the protect operation control unit.

A summary of this invention will be described briefly below.

This invention provides an electronic system including a semiconductor integrated circuit apparatus comprising: a nonvolatile semiconductor storage apparatus provided with a nonvolatile storage provided with a memory array unit having a plurality of nonvolatile memory cells and a control unit for controlling write operation of storing information in the nonvolatile memory cells, read operation of reading out the information stored in the nonvolatile memory cells, and erase operation of erasing the information stored in the nonvolatile memory cells; a volatile semiconductor storage apparatus to be used as a work area of a program stored in the nonvolatile semiconductor storage apparatus; a semiconductor integrated circuit apparatus provided with a central processing unit capable of executing a predetermined processing and giving instructions to the nonvolatile semiconductor storage apparatus a protect operation control unit for controlling the nonvolatile semiconductor storage apparatus and the read operation of the nonvolatile semiconductor storage apparatus, wherein the memory array unit has a first protect memory area in which reading of information stored is prohibited under the control of the protect operation control unit; the volatile semiconductor storage apparatus has a second protect memory area in which reading from an area other than the first protect memory area of the memory array unit is prohibited under the control of the protect operation control unit; and the second protect memory area is used as a work area of a program stored in the nonvolatile semiconductor storage apparatus.

### ADVANTAGE OF THE INVENTION

Brief description of effects to be obtained by the representative one of invention disclosed in this patent application is as follows.

(1) Prevention of illegal copying or alteration of a program and improvements in security thanks to restriction on reading/rewriting in a first protect memory block.

(2) More effective prevention of illegal copying or alteration of a program thanks to a restriction on reading in a second protect memory block which makes it difficult to guess the program.

(3) Significant improvement in reliability of a semiconductor integrated circuit apparatus and an electronic system using the semiconductor integrated circuit apparatus owing to the above items (1) and (2).

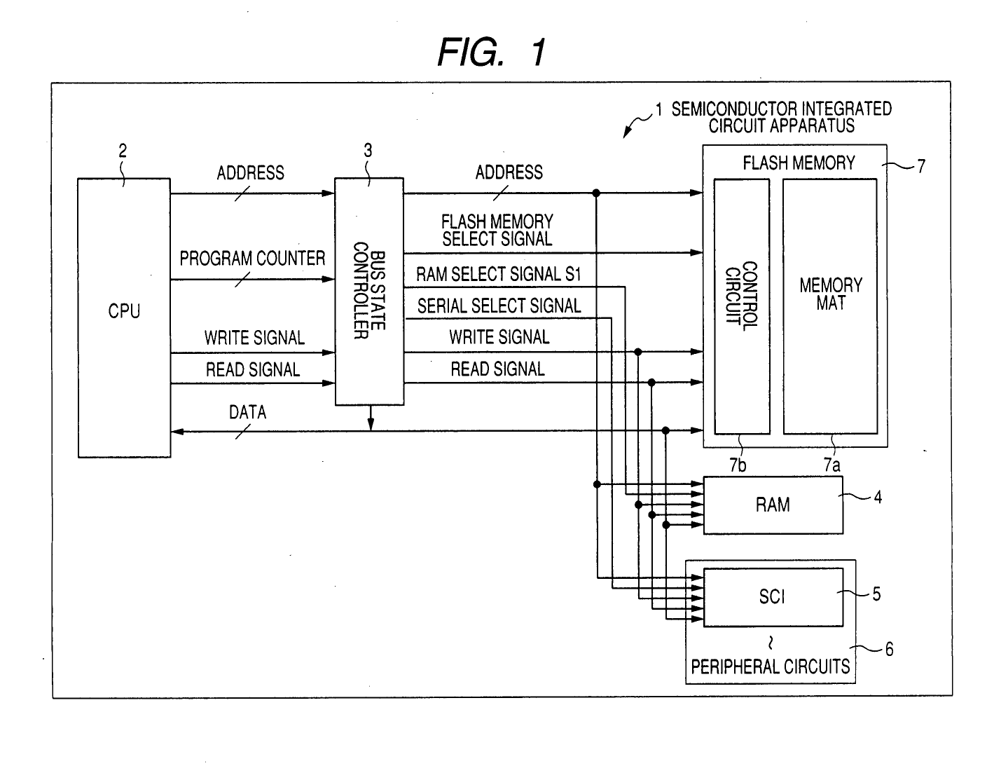

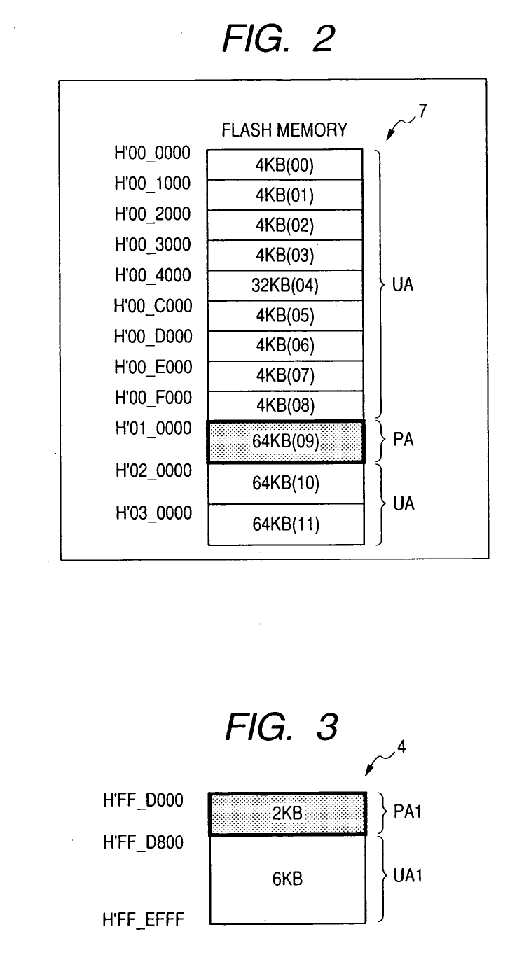

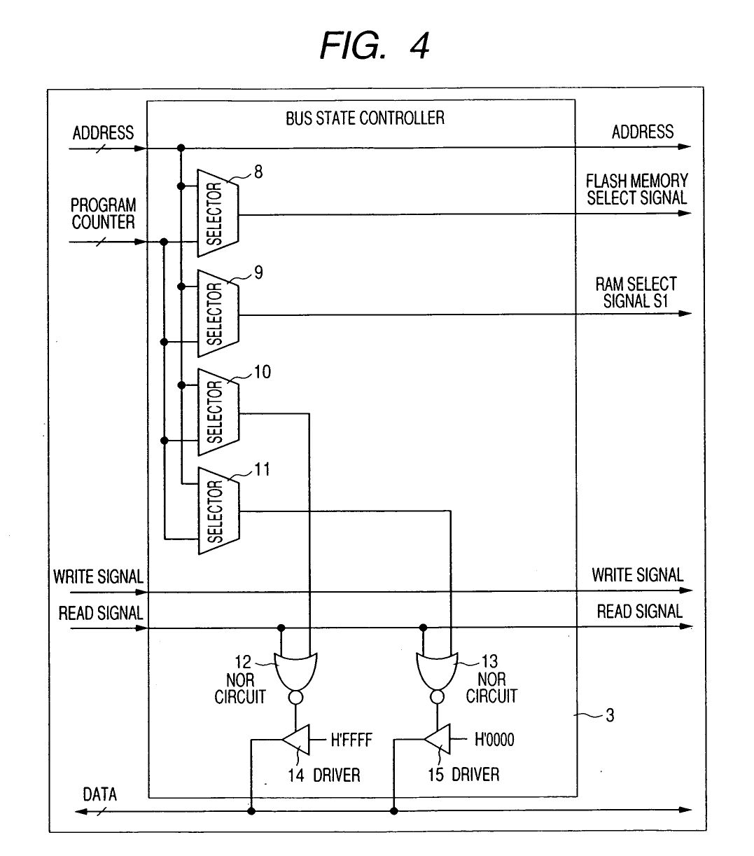

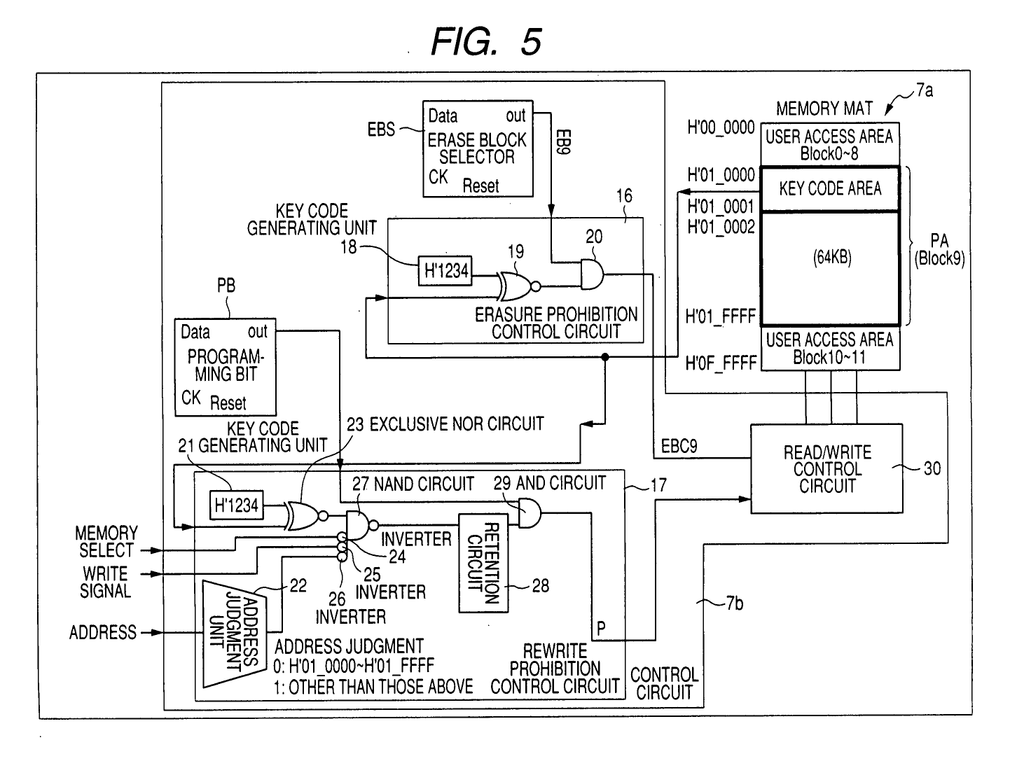

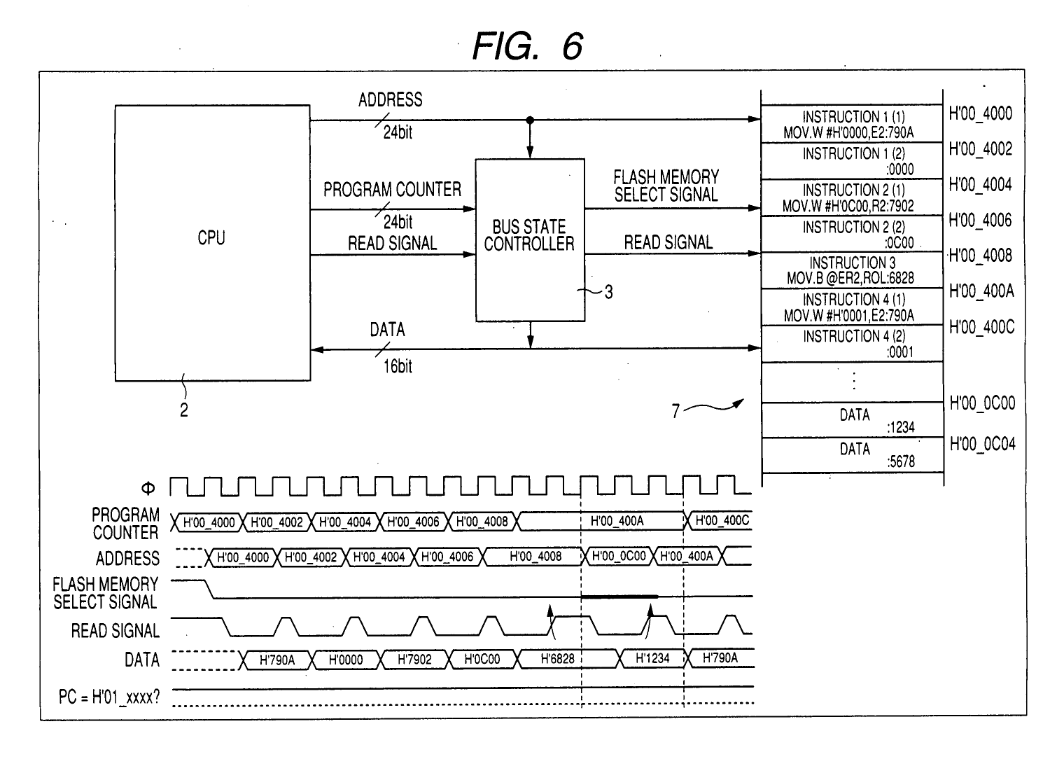

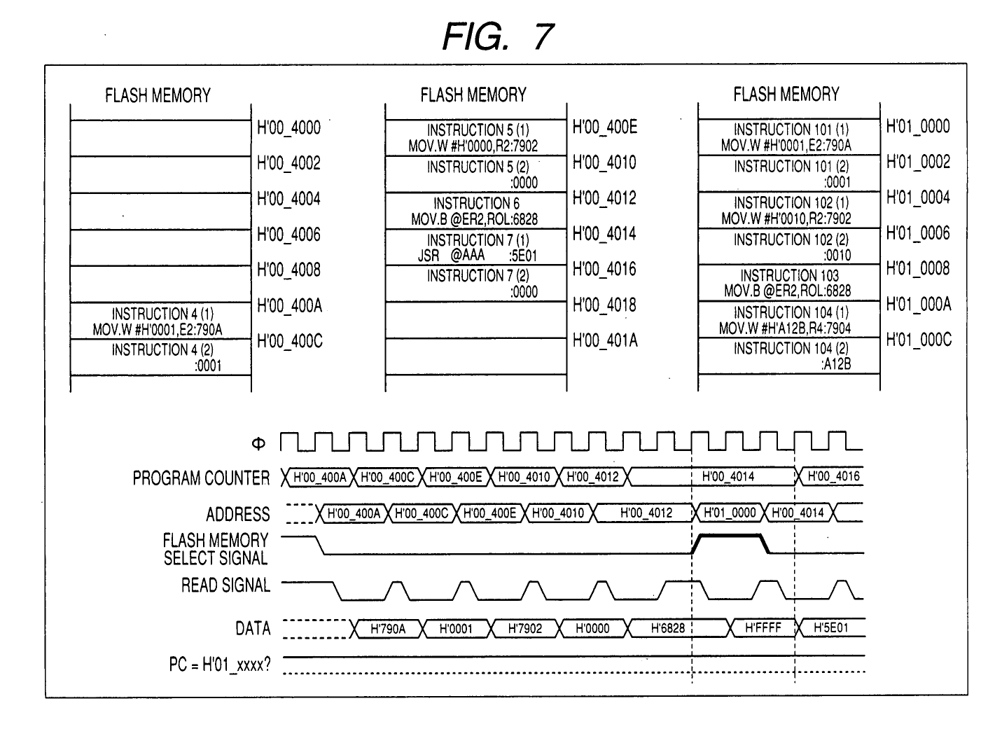

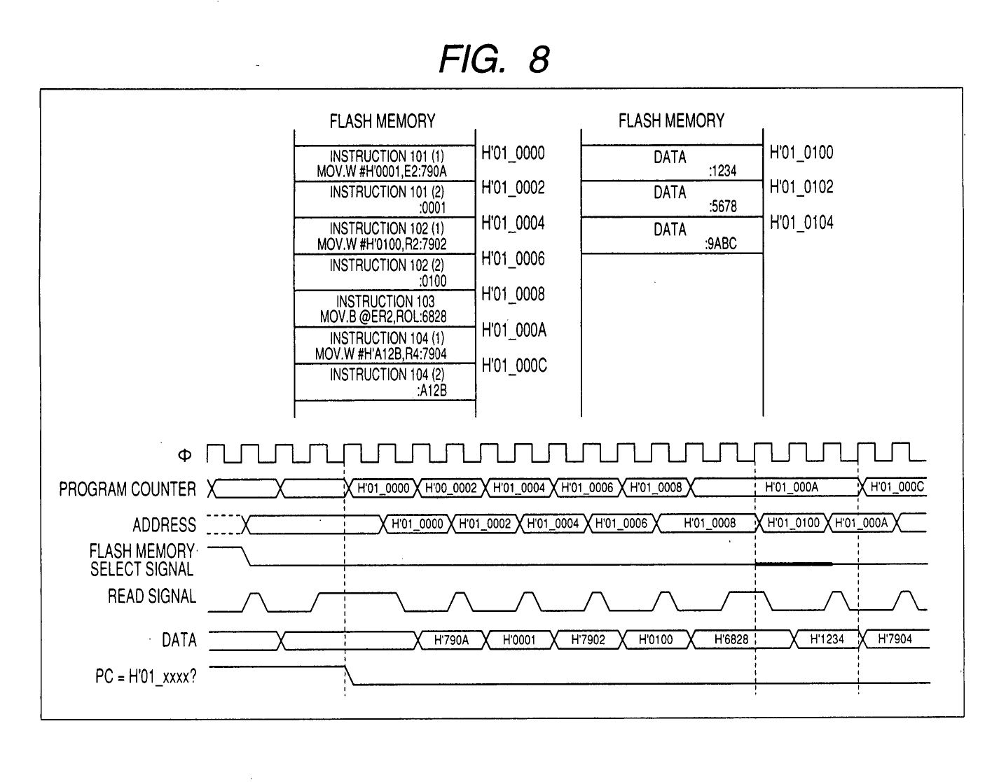

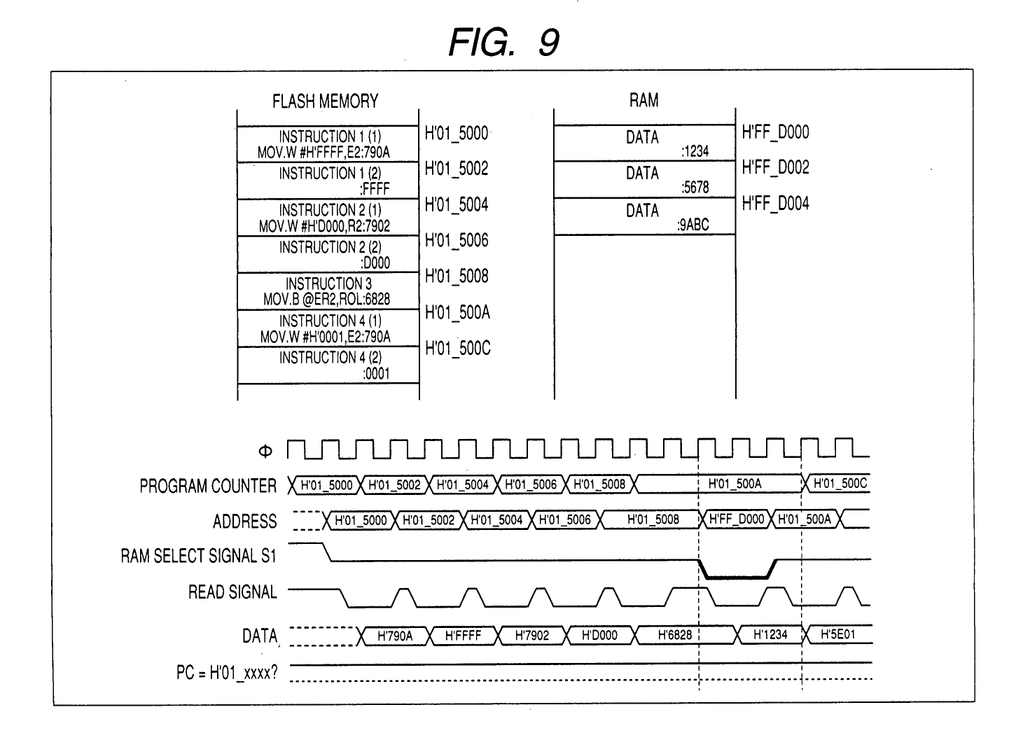

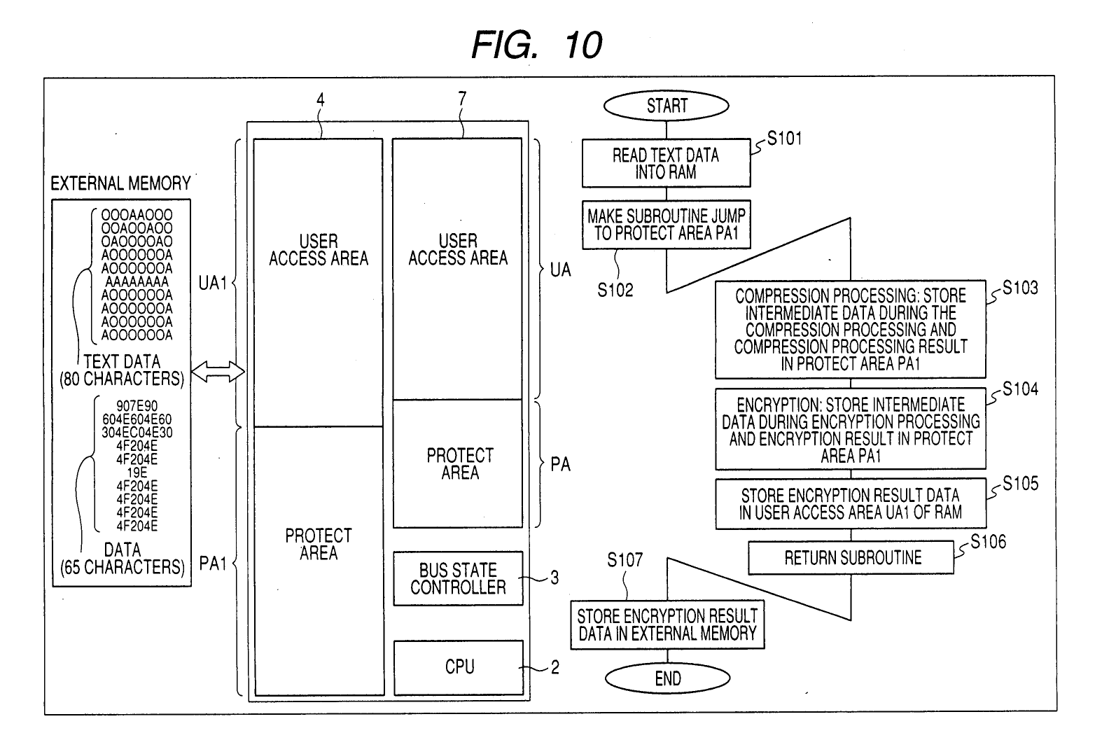

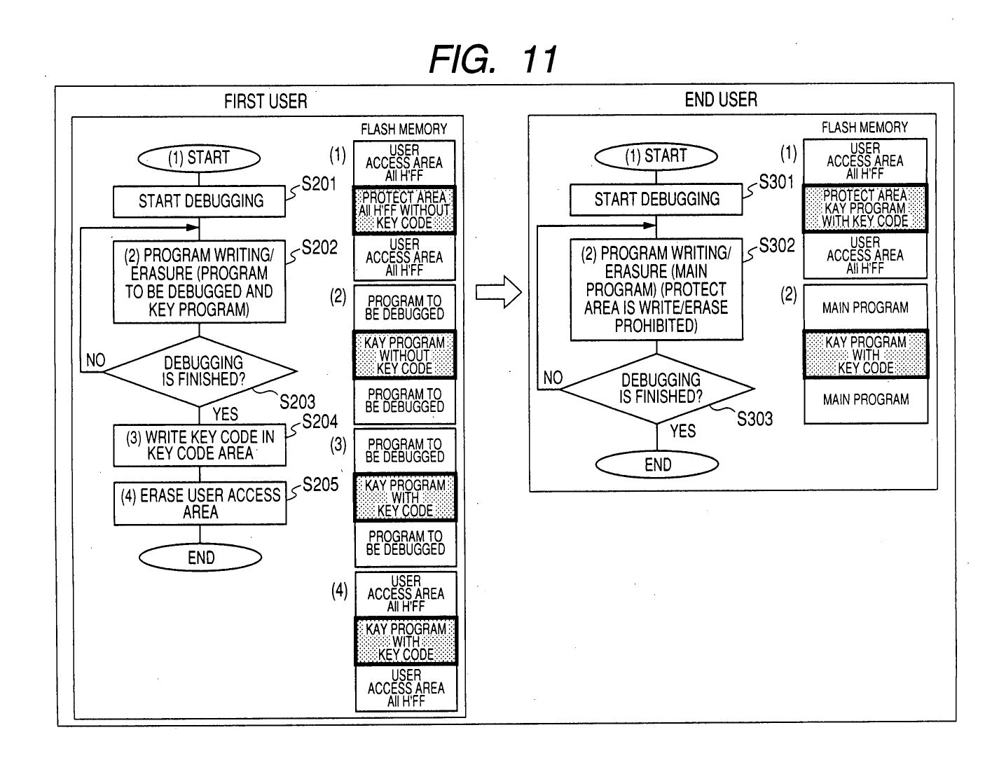

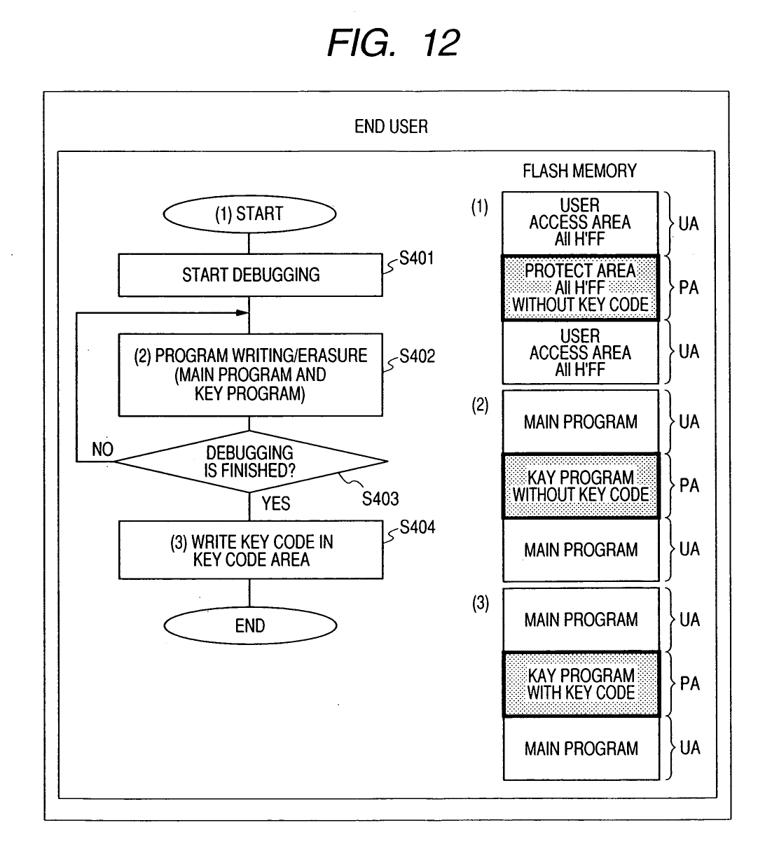

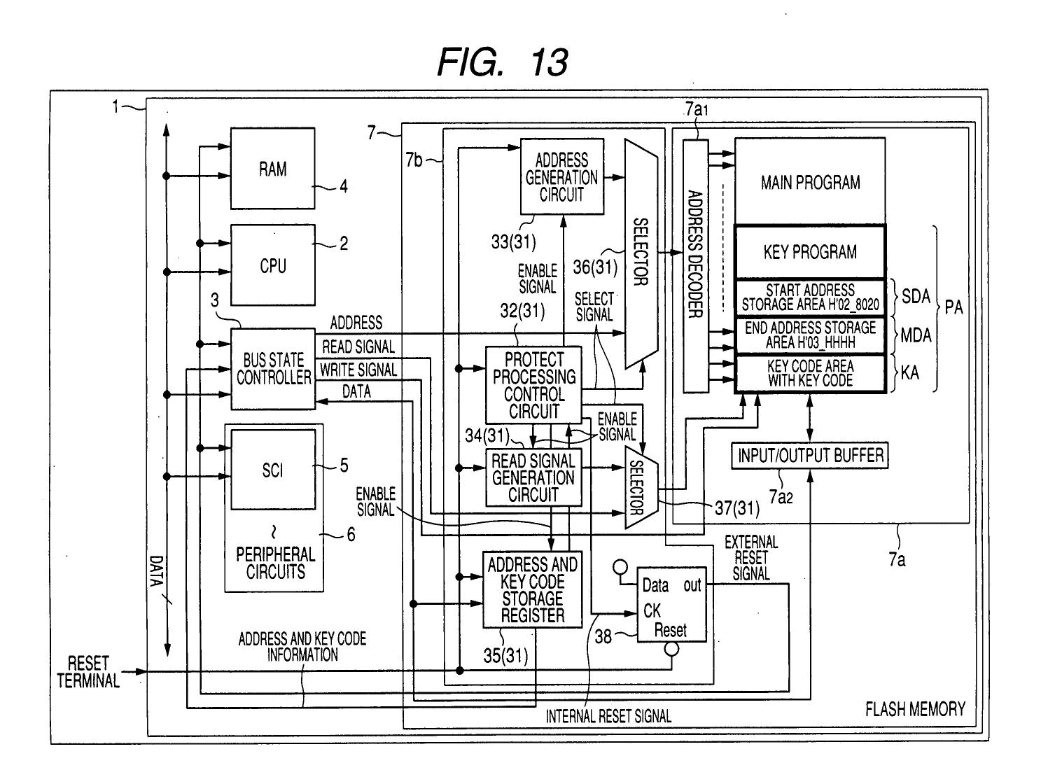

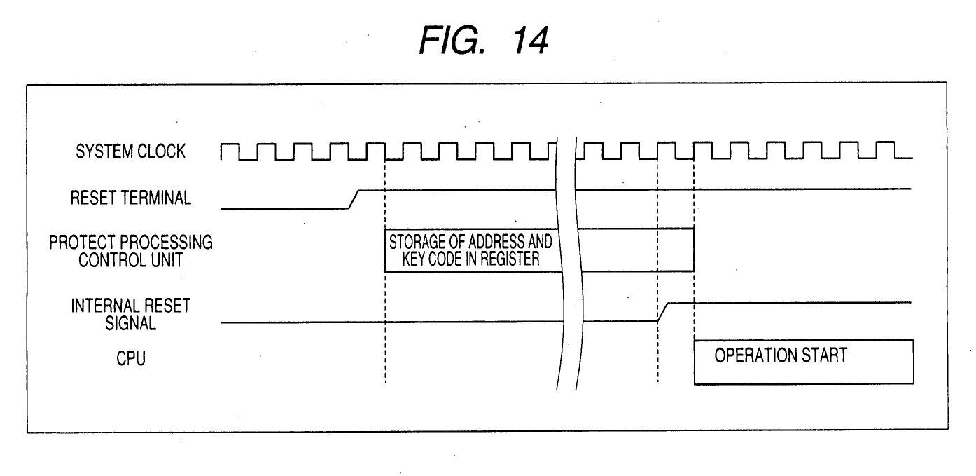

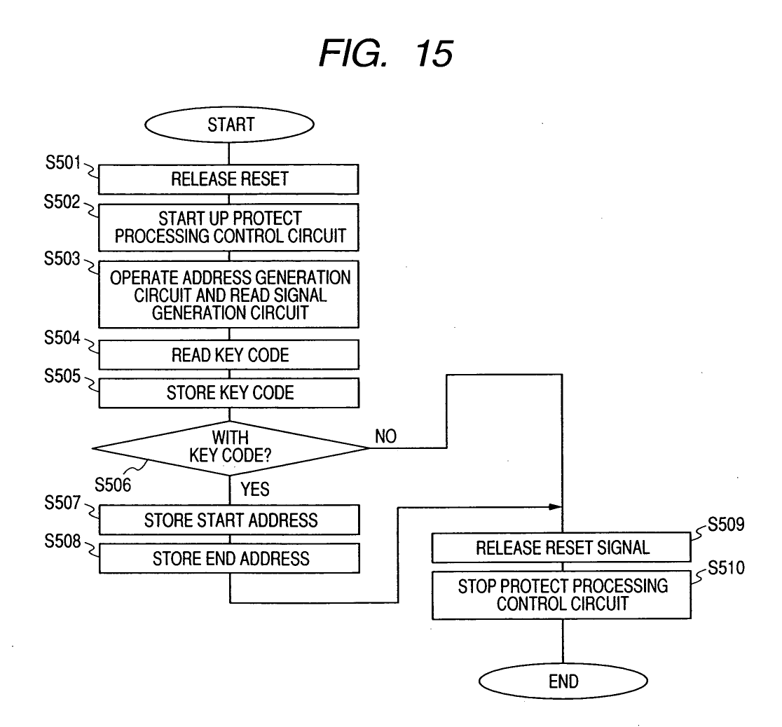

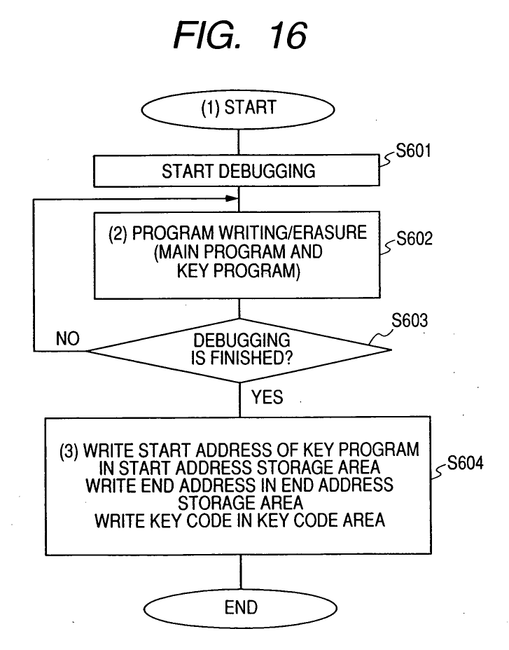

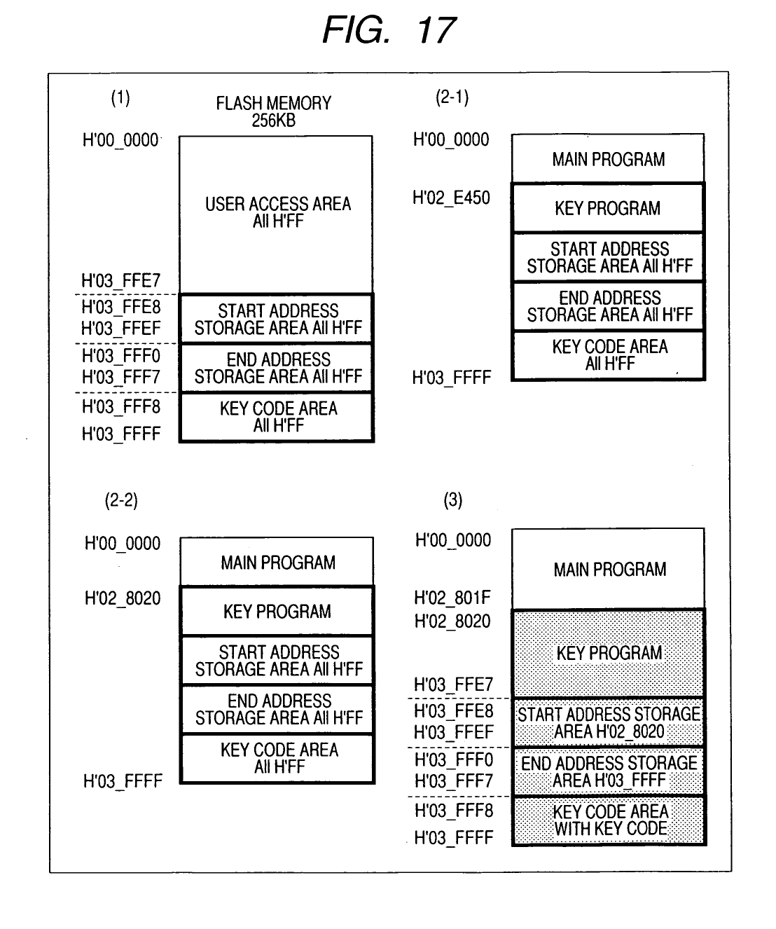

### BRIEF DESCRIPTION OF THE DRAWINGS

[FIG. 1] A block diagram showing a semiconductor integrated circuit apparatus according to a first embodiment of this invention.

[FIG. 2] A diagram for illustrating one example of a memory map in a flash memory provided in the semiconductor integrated circuit apparatus of FIG. 1.

[FIG. 3] A diagram for illustrating one example of a memory map in a RAM provided in the semiconductor integrated circuit apparatus of FIG. 1.

[FIG. 4] A diagram for illustrating a part of one example of constitution of a bus state controller provided in the semiconductor integrated circuit apparatus of FIG. 1.

[FIG. 5] A block diagram showing an erasure prohibition control circuit and rewrite prohibition control circuit provided in the semiconductor integrated circuit apparatus of FIG. 1.

[FIG. 6] A timing chart showing one example of reading control operation in a user access area of the flash memory provided in the semiconductor integrated circuit apparatus of FIG. 1.

[FIG. 7] A timing chart showing one example of control operation in the case of reading out a protect area from the user access area of the flash memory provided in the semiconductor integrated circuit apparatus of FIG. 1.

[FIG. 8] A timing chart showing one example of control operation in the case of reading out a protect area from a protect area of the flash memory provided in the semiconductor integrated circuit apparatus of FIG. 1.

[FIG. 9] A timing chart showing one example of control operation in the case of reading out data of a protect area of the RAM from the protect area of the flash memory provided in the semiconductor integrated circuit apparatus of FIG. 1.

[FIG. 10] A diagram for illustrating one example of processing of the RAM provided in the semiconductor integrated circuit apparatus of FIG. 1.

[FIG. 11] A flowchart showing one example of first user is setting up of a key code in the semiconductor integrated circuit apparatus of FIG. 1.

[FIG. 12] A flowchart showing one example of end user's setting up of a key code in the semiconductor integrated circuit apparatus of FIG. 1.

[FIG. 13] A block diagram showing a semiconductor integrated circuit apparatus according to a second embodiment of this invention.

[FIG. 14] A diagram for illustrating a reset sequence in the semiconductor integrated circuit apparatus of FIG. 13.

[FIG. 15] A flow chart showing a setting processing in a protect processing control unit in the reset sequence of FIG. 14.

[FIG. 16] A flowchart showing an arbitrary setting processing in a protect area in a flash memory provided in the semiconductor integrated circuit apparatus of FIG. 13.

[FIG. 17] A diagram for supplementary illustrating a memory map of the flash memory in FIG. 16.

### BEST MODE FOR CARRYING OUT THE INVENTION

Hereinafter, embodiments of this invention will be described in detail base on the drawings. Note that identical components are denoted by the same reference symbol as a general rule to omit repetitive description for such identical components.

### First Embodiment

FIG. 1 is a block diagram showing a semiconductor integrated circuit apparatus according to a first embodiment of this invention; FIG. 2 is a diagram for illustrating one example of a memory map in a flash memory provided in the semiconductor integrated circuit apparatus of FIG. 1; FIG. 3 is a diagram for illustrating one example of a memory map in a RAM provided in the semiconductor integrated circuit apparatus of FIG. 1; FIG. 4 is a diagram for illustrating a part of one example of constitution of a bus state controller provided in the semiconductor integrated circuit apparatus of FIG. 1; FIG. 5 is a block diagram showing an erasure prohibition control circuit and rewrite prohibition control circuit in the flash memory provided in the semiconductor integrated circuit apparatus of FIG. 1; FIG. 6 is a timing chart showing one example of reading control operation in a user access area of the flash memory provided in the semiconductor integrated circuit apparatus of FIG. 1; FIG. 7 is a timing chart showing one example of control operation in the case of reading out a protect area from the user access area of the flash memory provided in the semiconductor integrated circuit apparatus of FIG. 1; FIG. 8 is a timing chart showing one example of control operation in the case of reading out a protect area from a protect area of the flash memory provided in the semiconductor integrated circuit apparatus of FIG. 1; FIG. 9 is a timing chart showing one example of control operation in the case of reading out data of a protect area of the RAM from the protect area of the flash memory provided in the semiconductor integrated circuit apparatus of FIG. 1; FIG. 10 is a diagram for illustrating one example of processing of the RAM provided in the semiconductor integrated circuit apparatus of FIG. 1; FIG. 11 is a flowchart showing one example of first user's setting up of a key code in the semiconductor integrated circuit apparatus of FIG. 1; and FIG. 12 is a flowchart showing one example of end user's setting up of a key code in the semiconductor integrated circuit apparatus of FIG. 1.

In the first embodiment, a semiconductor integrated circuit apparatus 1 is provided with a CPU (Central Processing Unit) 2, a bus state controller (protect operation control unit) 3, a RAM (volatile storage) 4, peripheral circuits 6 including an SCI (Serial Communication Interface) 5, etc., a nonvolatile semiconductor memory such as a flash memory 7, and the like as shown in FIG. 1.

The CPU 2 reads out an instruction stored in the flash memory (nonvolatile storage) 7 to perform a predetermined processing. The bus state controller 3 controls transmission of signals in an internal bus B including an address bus and a data bus and controls a state of the internal bus B. The RAM (volatile storage) 4 is a readable/writable memory and used as a work area of the CPU 2.

The SCI 5 is an interface which performs serial communication with a device externally connected thereto. The peripheral circuit 6 is provided with a timer, a WDT (Watch Dog Timer), a TPU (Timer Pulse Unit), an A/D (Analog/Digital) converter, and a D/A (Digital/Analog) converter, and the like in addition to the above components.

The timer is based on an 8-bit counter, for example. The WDT monitors whether or not there is a runway of the semiconductor integrated circuit apparatus 1. The TPU is capable of outputting a PWM (Pulse Width Modulation) waveform. The A/D converter converts an analog signal into a digital signal to output the digital signal. The D/A converter converts a digital signal into an analog signal to output the analog signal.

The flash memory 7 is a nonvolatile semiconductor memory capable of electrically rewriting/erasing data and stores a control program including a program instruction to be executed by the CPU 2 and the like. The flash memory 7 performs data writing/reading, data erasure, and the like in response to instructions from the CPU 2.

The peripheral circuit 6 including the CPU 2, the bus state controller 3, the RAM 4, the SCI 5, and so forth and the flash memory 7 are connected to each other by the internal bus B.

The connection is so established that a value of a program counter indicating an address to be read out next, a write signal for permitting writing, and a read signal for permitting reading are input from the CPU 2 to the bus state controller 3.

Also, the connection is so established that a RAM select signal S1, a write signal, and a read signal output from the bus state controller 3 are input to the RAM 4. The RAM select signal S1 is used for selecting the RAM 4. The write signal is used for permitting writing in the RAM 4, and the read signal is a signal used for permitting reading in the RAM 4.

Also, the connection is so established that a serial select signal, a write signal, and a read signal are input to the SCI 5. The serial select signal is used for selecting the SCI 5. The write signal is used for permitting writing in the SCI 5, and the read signal is a signal used for permitting reading in the SCI 5.

Also, the connection is so established that a flash memory select signal, a write signal, and a read signal are input to the flash memory 7. The flash memory select signal is used for selecting the flash memory 7. The write signal is used for permitting writing in the flash memory 7, and the read signal is a signal used for permitting reading in the flash memory 7.

The flash memory 7 has a memory mat (memory array unit) 7a and a control circuit (control unit) 7b.

The memory mat 7a has memory cells, each of which is a smallest unit for storage, aligned in an array form and includes peripheral circuit such as an address buffer, a columndecoder, a row decoder, and sensing amplifier. The control circuit 7b temporarily stores various control signals input from the CPU 2 to control operation logic.

FIG. 2 is diagram for illustrating one example of the memory map in the memory mat 7a of the flash memory 7.

As shown in FIG. 2, the memory mat 7a has a user access area UA, and a protect area (first protect memory block) PA. The user access area UA has plural blocks to which a user can access. The protect area PA is a block in which programs and data are stored, and reading out of the programs and data is restricted. The protect area PA is not limited to one block of consecutive addresses and can be disposed in plural blocks.

FIG. 3 is a diagram for illustrating one example of the memory map in the RAM 4.

The memory map has a user access area UA1 and a protect area (second protect memory block) PA1 in the RAM 4, too. The user access area UA 1 is used for unfolding data of the flash memory 7 or the like, and the protect area PA 1 is a block used as a work area of the program stored in the protect area PA (first protect memory block) of the flash memory 7.

It is possible to read out the programs and data stored in the protect area PA of the memory mat 7a by the use of a program in the protect area PA, but reading out from the program stored in the user access area UA of the memory mat 7a, the user access area UA1 of the RAM 4, and the protect area PA1 is impossible.

It is possible to read out the data stored in the protect area PA1 of the RAM 4 from the protect area PA of the memory mat 7a, but reading out from areas other than the protect area PA (i.e. the user access area UA of the memory mat 7a, the user access area UA of the RAM 4, and the protect area PA1 of the RAM 4) is impossible.

Further, it is possible to rewrite/erase programs and data in the protect area PA of the flash memory 7 from the user access area UA1 of the RAM 4 until a predetermined key code is set in the key code area KA (FIG. 5) which will be described later in this specification. Until the setting of the predetermined key code, it is possible to gain access to the protect area PA, the user access area UA, and the user access area UA1 of the flash memory 7 from each of these areas.

In the case where the key code is set, it is impossible to rewrite/erase the protect area PA of the flash memory 7.

Though it is possible to rewrite/erase the data and the like stored in the protect area PA1 of the RAM 4 from the protect area PA of the flash memory 7, it is impossible to perform rewrite/erasure from areas other than the protect area PA (i.e. from the user access area UA of the flash memory 7, the user access area UA1 of the RAM 4, and the protect area PA1). Further, irrespective of the presence of the key code, rewrite/erasure from areas other than the protect area PA of the flash memory 7 is prohibited due to the control by the protect operation control unit.

In the case of reading out a program or data from the protect area PA in the flash memory 7 in which readout is prohibited, data of H'FF, for example, is invariably read out.

Though the data to be read out is referred to as H'FF in accordance with the data of initial value written in the flash memory 7 in this specification, the data to be read out may be any data other than data in a high impedance state (Hi-Z), such as senseless data including H'00 and a last value maintain, and an arbitrary value set by a user.

In the case of reading out a program or data of the protect area PA1 in RAM 4 in which read out is prohibited, data of H'00, for example, is invariably read out.

Though the data to be read out is referred to as H'00 in accordance with an NOP instruction of the RAM 4 in this specification, the data to be read out may be any of those other than data in a high impedance state (Hi-Z), such as senseless data including as H'FF and a last value maintain and an arbitrary value set by a user.

FIG. 4 is a diagram for illustrating a part of one example of constitution of the bus state controller 3.

The bus state controller 3 has selectors 8 to 11, NOR circuits 12 and 13, drivers 14 and 15, and the like as shown in FIG. 4.

An address signal is input to one of input units of each of the selectors 8 to 11 from the CPU 2 (FIG. 1), and a program counter value (PC value) output from the CPU 2 is input to the other one of input units of each of the selectors 8 to 11.

The selector 8 outputs ‘0’ (Lo level signal) which brings the flash memory select signal active in the case where the address signal is an address H'00_{—}0000 to H'00_FFFF or an address H'02_{—}0000 to H'03_FFFF, or an address H'01_{—}0000 to H'01_FFFF indicating the protect area PA (FIG. 2) of the flash memory 7 and a value of the program counter is H'01_{—}0000 to OL_FFFF. In other cases, the selector 8 outputs ‘1’ (Hi level signal) which brings the flash memory select signal inactive. That is, it is possible to gain access irrespective of the program counter value in the case where the address value output from the CPU 2 indicates the user access area UA of the flash memory 7. Further, in the case where the address value indicates the protect area PA of the flash memory 7 and the value of the program counter indicates the protect area PA of the flash memory 7, too, the flash memory 7 is in an accessible state, i.e., the select signal is in the active state.

The selector 9 outputs ‘0’ (Lo level signal) which brings the RAM memory select signal active in the case where the address signal is an address H'FF_D800 to H'FF_EFFF which indicates the user access area UA1 (FIG. 3) of the RAM 4 or an address H’FF_D000 to H'FF_D7FF which indicates the protect area PA1 (FIG. 3) of the RAM 4 and a value of the program counter is H'01_{—}0000 to 01_FFFF (address indicating the protect area PA of the flash memory 7). In other cases, the selector 9 outputs ‘1’ (Hi level signal) which brings the RAM select signal inactive. That is, it is possible to gain access irrespective of the program counter value in the case where the address value output from the CPU 2 indicates the user access area UA1 of the RAM 4. Further, in the case where the value of the program counter indicates the protect area PA of the flash memory 7 and the address value indicates the protect area PA1 of the RAM 4, the RAM 4 is in an accessible state.

The selector 10 outputs ‘0’ in the case where the address signal is an address H'01_{—}0000 to H'01_FFFF indicating the protect area PA (FIG. 2) of the flash memory 7 and the value of the program counter is a value other than H'01_{—}0000 to 01_FFFF. The selector 10 outputs ‘1’ when the address signal is the address H'01_{—}0000 to H'01_FFFF and the program counter value is H'01_{—}0000 to 01_FFFF.

The selector 11 outputs ‘0’ in the case where the address signal is the address H'FF_D000 to H'FF_D7FF which indicates the protect area PA1 of the RAM 4 and the value of the program counter is a value other than H'01_{—}0000 to 01_FFFF. The selector 11 outputs ‘1’ when the address signal is the address H'FF_D000 to H'FF_D7FF and the program counter value is H'01_{—}0000 to 01_FFFF.

Thus, the select conditions for reading/writing in the protect area PA of the flash memory 7 are such that the flash memory select signal is enabled only in the case where the program counter value and the address signal value coincide with the protect area PA of the flash memory 7. The flash memory select signal is disabled in cases other than the above case.

In the RAM 4, the select conditions for reading/writing in the protect area PA1 of the RAM 4 are such that the RAM select signal is enabled only in the case where the program counter value indicates the protect area PA of the flash memory 7 and the address signal value indicates the protect area PA1 of the RAM 4. The RAM select signal is disabled in cases other than the above case.

The NOR circuit 12 finds a NOR sum of the signal output from the selector 10 and the read signal to output the NOR sum to the control unit of the driver 14. In the case where the address signal is the address H'01_{—}0000 to H'01_FFFF indicating the protect area PA of the flash memory 7, the program counter value is a value other than H'01_{—}0000 to 01_FFFF, and the active read signal (‘0’) is input, the NOR circuit 12 outputs a control signal so that the driver 14 outputs the initial value of the flash memory 7 H'FFFF. In accordance with the above control, H'FFFF is output to the data signal of the internal bus B. The value of the output signal is not limited to H'FFFF, and it is possible to arbitrarily set the output value. That is, any value may be output as long as the value is not the read out data from the flash memory 7 in accordance with the address signal output from CPU 2.

The NOR circuit 13 finds a NOR sum of the signal output from the selector 11 and the read signal to output the NOR sum to the control unit of the driver 15. In the case where the address signal is the address H'FF_D0000 to H'FF_D7FF which indicates the protect area PA1 of the RAM 4, the program counter value is a value other than H'01_{—}0000 to 01_FFFF, and the active read signal (‘0’) is input, the NOR circuit 13 outputs a control signal so that the driver 15 outputs the value corresponding to the NOP instruction from the RAM 4. In accordance with the above control, H'0000 is output to the data signal of the internal bus B. The value of the output signal is not limited to H'0000, and it is possible to arbitrarily set the output value. That is, any value may be output as long as the value is not the read out data from the RAM 4 in accordance with the address signal output from CPU 2.

In the case where the flash memory 7 or ‘0’) is output and the flash memory select signal and the RAM select signal are disabled, access to the flash memory 7 and the RAM 4 is prohibited to bring the data signal into a state of last value maintain.

FIG. 5 is a block diagram showing an erasure prohibition control circuit (erasure prohibition control unit) 16 and a rewrite prohibition control circuit (rewrite prohibition control unit) 17 provided in the control circuit 7b controlling operation of the flash memory 7.

The erasure prohibition control circuit 16 is a circuit for controlling erasure prohibition of the flash memory 7. In the case where a key code (first setting value) which is previously written in the key code area KA of the memory mat 7a coincides with the key code (second setting value) which is previously set, the erasure prohibit control circuit 16 prohibits erasure of a protect area PA of the memory mat 7a in the case where data erasure occurs in the protect area.

The erasure prohibition control circuit 16 has a key code generation unit (key code generation circuit) 18, an exclusive NOR circuit (erasure control circuit) 19, and an AND circuit 20 (erasure control circuit). The key code generation unit 18 has a circuit which outputs the previously set key code (second setting value such as H'1234, for example) by the use of hardware.

Connection is established in such a fashion that the key code (H'1234) generated by the key code generation unit 18 is input to one of input units of the exclusive NOR circuit 19 and that the key code (first setting value) stored in the key code area KA is input to the other input unit of the exclusive NOR circuit 19.

Connection is established in such a fashion that an erase block signal EB9 output from an erase block selector EBS is input to one of input units of the AND circuit 20. The erase block selector EBS is provided in the control circuit 7b and serves as one of registers for selecting a block to be erased. The erase bock selector EBS outputs the erase block signal EB9 of ‘0’ when erasing the protect area PA (Block 9) in the memory mat 7a of flash memory 7.

Connection is established in such a fashion that a signal output from the exclusive NOR circuit 19 is input to the other input unit of the AND circuit 20. An input unit of a read/write control circuit 30 for controlling read/write in the flash memory 7 is connected to an output unit of the AND circuit 20, and an erase block control signal EBC9 is output from the output unit of the AND circuit 20.

In the case where the key code (second setting value) generated by the key code generating unit 18 coincides with the key code (first setting value) stored in the key code area, the erasure prohibition control circuit 16 performs its control so as to disable the erase block control signal, and the read/write control circuit 30 prohibits erase operation.

In the case where the erase block control signal EBC9 is enabled, the read/write control circuit 30 performs erase control on the protect area PA (Block 9).

In the case of setting plural protect areas in the memory cell unit of the flash memory 7, the erasure prohibition control circuit 16 is provided in each of the protect areas to perform the erase control on the plural protect areas.

The rewrite prohibition control circuit 17 has a key code generation unit (key code generation circuit) 21, an address judgment unit (address judgment circuit) 22, an exclusive NOR circuit (key code judgment unit) 23, inverters (rewrite control circuits) 24 to 26, a NOR circuit (rewrite control circuit) 27, a retention circuit (rewrite control circuit) 28, and an AND circuit (rewrite control circuit) 29.

The key code generation unit 21 has a circuit which outputs a previously set key code (third setting value, for example, H'1234) by the use of hardware. Connection is established in such a fashion that the key code (H'1234) generated by the key code generation unit 18 is input to one of input units of the exclusive NOR circuit 23 and that the key code (first setting value) stored in the key code area KA is input to the other input unit of the exclusive NOR circuit 23.

An address signal is input to the address judgment unit 22, and the address judgment unit 22 output ‘0’ when the address signal is the address H'01_{—}0000 to H'01_FFFF and outputs ‘1’ when the address signal is other than the address H'01_{—}0000 to H'01_FFFF.

Connection is established in such a fashion that the memory select signal (FIG. 1), the write signal (FIG. 1), and a judgment signal output from the address judgment unit 22 are input to input units of the inverter 24 to 26.

An output unit of the exclusive NOR circuit 23 and output units of the inverter 24 to 26 are connected to an input unit of the NOR circuit 27, and an input unit of the retention circuit 28 is connected to an output unit of the NOR circuit 27. The retention circuit 28 is a circuit which retains a state of a signal until writing in the flash memory 7 occurs.

Connection is established in such a fashion that a program mode signal P output from a programming bit PB is input to one of input units of the AND circuit 29. The programming bit PB is a bit used for releasing/transitioning a program mode for starting rewriting. The program mode is released when the programming bit PB is ‘0’, while the transition to the program mode is performed when the programming bit PB is ‘1’.

An input unit of a read/write control circuit 30 is connected to an output unit of the AND circuit 29, and a program mode signal P is output from the output unit of the AND circuit 29.

In the case where the key code (third setting value) generated by the key code generation unit 21 coincides with the key code (first setting value) stored in the key code area, the read/write control circuit 30 prohibits rewrite operation.

In the case where the program mode signal P is enabled, the read/write control circuit 30 performs rewrite control on the protect area PA (Block 9).

Though the key code is set to H'1234 in this specification, the key code may be any data other than the initial value (H'FFFF) stored in the flash memory 7.

Hereinafter, operation of the semiconductor integrated circuit apparatus 1 according to this invention will be described.

The instruction shown in FIGS. 6 to 9 as the instruction to be executed by the CPU 2 is not more than one specific example. The instruction is not limited to the above one, and various instructions can be executed. Instruction stored in a memory corresponding to an address and a data value (for example, “H'6828” is stored in the address H'00_{—}4008 in FIG. 6) vary from program to program. In this invention, accesses to the various memories and peripheral circuits are controlled through a comparison between the address value and the program counter value performed by the bus state controller 3.

To start with, readout control operation in the user access area UA of the flash memory 7 will be described using FIG. 6.

An illustration of the readout control by the flash memory 7 is shown in an upper part of FIG. 6, and a timing chart of the signals of relevant units is shown in a lower part of FIG. 6.

In the timing chart of FIG. 6, a clock signal φ, a program counter value output from the CPU 2, an address signal output from the CPU 2, a flash memory select signal output from the bus state controller 3, a data signal output from the CPU 2, and a state signal (PC=H'01_xxxx) indicating whether the program counter value indicates the protect area PA of the flash memory 7 are shown in this order from the top to the bottom.

The program counter of the CPU 2 indicates and address H'00_{—}4000 to output the address H'00_{—}4000 to the internal bus so that CPU 2 reads out an instruction in the address H'00_{—}4000 from the memory sequentially. Then, the CPU 2 stores H'0000 in a general purpose register (E2).

After that, the CPU 2 reads out an instruction of an address H'00_{—}4004 and then an address H'00_{—}4006 to store H'0C00 in a general purpose register (R2).

Then, the CPU 2 reads out an instruction of an address H'00_{—}4008 to analyze the instruction (to read data stored in a memory indicated by the address value of the general purpose register ER2). After that, the CPU 2 executes the instruction and reads out data of an address H'00_{—}0C00 to store H'1234 in a general purpose register (ROL).

In this case, the protect area PA in the flash memory 7 is not read out, i.e., the address value does not indicate the protect area PA, so that programs/data are read out without limitation.

Hereinafter, control operation for reading out the protect area PA from the user access area UA of the flash memory 7 will be described with reference to FIG. 7.

An illustration of the readout control by the flash memory 7 is shown in an upper part of FIG. 7, and a timing chart of the signals of relevant units is shown in a lower part of FIG. 7. In the timing chart, a clock signal φ, a program counter value output from the CPU 2, a address signal output from the CPU 2, a flash memory select signal output from the bus state controller 3, data, and a state signal (PC=H'01_xxxx?) indicating whether the program counter value indicates the protect area PA of the flash memory 7 are shown in this order from the top to the bottom.

The program counter of the CPU 2 indicates an address H'00_{—}400A and outputs the address H'00_{—}400A to the internal bus. Instructions of the address H'00_{—}400A are read out sequentially from the memory to store H'0001 in the general purpose register (E2). Then, the CPU 2 reads out an address H'00_{—}400E and an address H'00_{—}4010 sequentially to store H'0000 in the general purpose resister (R2). Then, the CPU2 reads out the instruction of the address H'00_{—}4012 to perform analysis (to read data stored in the memory indicated by the address value indicated by the general purpose register ER2) and then reads out data of the address H'01_{—}0000.

In this case, the address H'01_{—}0000 is inside the protect area PA of the flash memory 7, and the program counter value output from the CPU 2 is outside the protect area PA (H'00_{—}4014 in this case), so that the flash memory select signal output from the bus state controller 3 is inactive (‘1’) to cause the data of H'FFFF to be output to the address signal of the internal bus B under the control of the bus state controller 3.

With the above-described constitution, it is possible to prohibit data read access to the protect area PA from the user area UA.

Hereinafter, control operation for reading out the protect area PA from the protect area PA of the flash memory 7 will be described using FIG. 8.

An illustration of the readout control by the flash memory 7 is shown in an upper part of FIG. 8, and a timing chart of the signals of relevant units is shown in a lower part of FIG. 8. In the timing chart, a clock signal φ, a program counter value output from the CPU 2, an address signal output from the CPU 2, a flash memory select signal output from the bus state controller 3, data, and a state signal (PC=H'01_xxxx?) indicating whether the program counter value indicates the protect area PA of the flash memory 7 are shown in this order from the top to the bottom.

The CPU 2 reads out instructions stored in an address H'01_{—}0000 and an address H'01_{—}0002 sequentially to store H'0001 in the general purpose register (E2). After that, the CPU 2 reads out instructions of the address H'01_{—}0004 and the address H'01_{—}0006 to store H'0100 in the general purpose register (R2).

Then, the CPU 2 reads out an instruction of an address H'01_{—}0008 to perform analysis (to read data stored in the memory indicated by the address indicated by the general purpose register ER2) and then executes the instruction based on the analysis to read out data to be stored in the address H'01_{—}0100, whereby the CPU 2 stores H'1234 in the general purpose register (ROL).

In this case, since the protect area PA is read out from the protect area PA, the program counter value is in the protect area PA, and the flash memory select signal is continuously active (‘0’), so that normal data read out from the flash memory 7 are output to the data signal (Data) of the internal bus B.

Hereinafter, control operation for reading out data of the protect area PA1 of the RAM 4 from the protect area PA of the flash memory 7 will be described using FIG. 9.

Illustrations for read out controls by the flash memory 7 and the RAM 4 are shown in an upper part of FIG. 9, and timing charts of signals are shown in a lower part of FIG. 9. In the timing chart, a clock signal φ, a program counter value output from the CPU 2, an address signal output from the CPU 2, a RAM memory select signal output from the bus sate controller 3, data, and a state signal (PC=H'01_xxxx?) indicating whether the program counter value indicates the protect area PA of the flash memory 7 are shown in this order from the top to the bottom.

The CPU 2 reads out instructions of an address H'01_{—}5000 and an address H'01_{—}5002 sequentially to store H'FFFF in the general purpose register (E2). After that, the CPU 2 reads out instructions of an address H'01_{—}5004 and an address H'01_{—}5006 sequentially to store H'D000 in the general purpose register (R2).

After that, CPU 2 reads out an instruction of an address H'01_{—}5008 to perform analysis of the instruction (to read data stored in the memory indicated by the address indicated by the general purpose register ER2), and the CPU 2 reads out data of an address H'FF_D000 in the RAM 4 to store the read out H'1234 in the general purpose register (ROL).

In this case, since the program counter value (H'01_{—}50xx) is in the protect area PA1, the RAM select signal output from the bus state controller 3 becomes active (‘0’) to bring normal data to be read out from the RAM 4.

One example of processing by the RAM 4 used as the work area will be described by using FIG. 10.

Referring to FIG. 10, a process of compressing text data will be described. A left part of FIG. 10 is an illustration of the RAM 4 and the flash memory 7, and a right part is a flowchart of the processing.

The text data are unfolded on the RAM 4 (Step S101), and then a subroutine jump to the protect area PA1 of the RAM 4 (Step S102) is performed. After that, during the compression processing based on the program stored in the protect area PA, intermediate data in the compression processing and a compression processing result are stored in the protect area PA 1 (step S103).

Then, in an encryption processing based on a program stored in the protect area PA, intermediate data for the encryption processing and an encryption result are stored in the protect area PA1 (Step S104) and the encryption result data are stored in the user access area UA1 (Step S105).

After that, by means of return subroutine (Step S106), the encryption result data are stored in an external memory, for example, which is externally connected to the semiconductor integrated circuit apparatus 1 (Step S107).

By performing the program processing of compression and encryption in the protect area PA1 of the RAM 4 as described above, it is possible to make it difficult to guess what processing is performed by the program.

Hereinafter, operations of the erasure prohibition control circuit 16 and the rewrite prohibition control circuit 17 provided in the control circuit 7b shown in FIG. 5 will be described.

When a block (Block 9) is specified in erase operation of the flash memory 7, an erase block signal EB9 of ‘0’ is output from the erase block selector EBS.

In this case, the erasure prohibition control circuit 16 reads out a key code (first setting value) stored in a key code area KA and finds an exclusive NOR sum of the key code and a key code (second setting value) generated by the key code generation unit 18 by the use of the exclusive NOR circuit 19. In the case where the readout key code and the key code generated by the key code generation unit 18 coincides with each other, an erase block control signal EBC of ‘0’ is input to the read/write control circuit 30. The erase operation in the flash memory 7 is prohibited by the erase block control signal EBC9.

In the rewrite operation of the flash memory 7, a program mode signal P of ‘1’ is output from the programming bit PB, and then an address specifying designation of the rewrite is input.

The address judgment unit 22 judges whether the input address signal is in the protect area PA or not. A key code (third setting value) generated by the key code generation unit 21 is compared with the key code (first setting value) stored in the key code area KA in the exclusive NOR circuit 19, and a signal of ‘0’ is output in the case where the key codes coincides with each other.

Further, since the flash memory 7 is to be rewritten, an active (‘0’) flash memory select signal and an active write signal is output from the bus state controller 3.

In the case where the input address is in the protect area PA, a signal ‘0’ is output from the address judgment unit 22 to be input to the other input unit of the AND circuit 29 via the retention circuit 28.

Since the program mode signal P of ‘1’ is output from the programming bit PB, a program mode signal P of ‘0’ is output to the read/write control circuit 30 from the AND circuit 29. Thus, rewrite operation in the flash memory 7 is prohibited.

Since a signal of ‘1’ is output from the address judgment unit 22 in the case where the input address is outside the protect area PA, the program mode signal P output from the AND circuit 29 becomes ‘1’ to rewrite the flash memory 7.

Hereinafter, a processing to be performed in the case where a first user (soft IP vender, for example) dispatches a semiconductor integrated circuit apparatus 1 to an end user after writing a program and setting a key code in the semiconductor integrated circuit apparatus 1 will be described using a flowchart of FIG. 11.

The first user starts debugging of a key program (first program) created by the first user (Step S201). Write and erasure of the key program (Step S202) are performed until completion of the debugging (Step S203). After the completion of debugging, a key code (first setting value) is written in a key code area KA (Step S204), and a program for debugging (third program) stored in the user access area UA and the like are erased for the dispatch to the end user (Step S205).

After that, the end user starts debugging of a main program (second program) created by the end user (Step S301). Write and erasure of the main program generated by the debugging are performed until completion of the debugging (Steps S302 and S303).

Since the key code is set by the first user in processing of these steps S302 and S303, it is impossible for the end user to perform write/erase of the program (first program) written by the first user and stored in the protect area PA.

Hereinafter, a processing to be performed when the end user sets a key code will be described using FIG. 12.

The end user starts debugging a key program (first program) to be stored in the protect area PA and a main program (second program) to be stored in the user area (Step S401). Then, writing and erasure of the key program (first program) and the main program (second program) generated by the debugging are performed (Step S402).

After completion of the debugging (Step S403), a key code (a first setting value) is written in the key code area to protect the key program written in the protect area PA (Step S404).

According to the first embodiment, since it is possible to protect the key program, reading and copying or alteration of the key program by a third party are prevented.

### Second Embodiment

FIG. 13 is a block diagram showing a semiconductor integrated circuit apparatus according to a second embodiment of this invention; FIG. 14 is a diagram for illustrating a reset sequence in the semiconductor integrated circuit apparatus of FIG. 13; FIG. 15 is a flow chart showing a setting processing in a protect processing control unit in the reset sequence of FIG. 14; FIG. 16 is a flowchart showing a arbitrary setting processing in a protect area in a flash memory 7 provided in the semiconductor integrated circuit apparatus of FIG. 13; and FIG. 17 is a diagram for supplementary illustrating a memory map of the flash memory 7 in FIG. 16.

In the second embodiment, a semiconductor integrated circuit apparatus 1 is provided with a CPU 2, a bus state controller 3, a RAM 4, peripheral circuits 6 including an SCI (Serial Communication Interface) 5, etc., a nonvolatile semiconductor memory such as a flash memory 7, and the like as shown in FIG. 13, and the constitution is the same as that of the first embodiment 1.

Though the protect area PA of the flash memory 7 is fixed to one block containing addresses H'01_{—}0000 to H'01_FFFF, it is possible to arbitrarily change the protect area PA of the flash memory 7 in the second embodiment.

The flash memory 7 has a memory mat 7a and a control circuit 7b. The memory mat 7a has memory cells, each of which is a smallest unit for storage, aligned in an array form and includes peripheral circuit such as an address buffer, an address decoder 7a1, an input output buffer 7a2, and a sensing amplifier.

The control circuit 7b temporarily stores various control signals input from the CPU 2 to control operation logic. The control circuit 7b is provided with a protect processing control unit 31.

The protect processing control unit 31 performs control on arbitrarily changing an area of the protect area PA in the flash memory 7. The protect area PA is provided with a start address storage area SDA for storing a start address of the protect area PA, an end address storage area MDA for storing an end address of the protect area PA, and a key code area KA for storing a key code area.

The protect processing control unit 31 has a protect processing control circuit 32, an address generation circuit 33, a read signal generation circuit 34, an address/key code storage register 35, and selectors 36 and 37.

Connection is established in such a fashion that a reset signal output from a reset circuit 38 for generating a reset signal is input to the protect processing control circuit 32, the address generation circuit 33, the read signal generation circuit 34, and the address/key code storage register 35.

The address generation circuit 33, the read signal generation circuit 34, and the address/key code storage register 35 are connected to the protect processing control circuit 32, and a signal output from the protect processing control circuit 32 causes the circuits to start operation.

The address generation circuit 33 generates a storage address for storing a key code stored in the memory mat 7a of the flash memory 7. The read signal generation circuit 34 generates a read signal of the memory mat 7a. The address/key code storage register 35 stores the key code read out from the memory mat 7a and an address indicating an area of the protect area PA.

Connection is established in such a fashion that control signals for controlling the selectors 36 and 37 are input to the protect processing control circuit 32. The selector 36 switches between the address generated by the address generation circuit 33 and the address output from the bus state controller 3 based on the control signal output from the protect processing control circuit 32 to output one of the addresses.

The selector 37 switches between the read signal generated by the read signal generation circuit 34 and the road signal output from the bus state controller 3 based on the control signal output from the protect processing control circuit 32 to output.

FIG. 14 is a diagram for illustrating a reset sequence in the semiconductor integrated circuit apparatus 1; FIG. 15 is a flow chart showing a setting processing in the protect processing control unit 31 in the reset sequence in FIG. 14.

In FIG. 14, a system clock, a reset signal input to a reset terminal of a semiconductor integrated circuit apparatus 1, a operation state of the protect processing control unit 31, an internal reset signal of the semiconductor integrated circuit apparatus 1, and an operation state of the CPU (semiconductor integrated circuit apparatus 1) 2 are shown in this order from the top to the bottom.

To start with, a reset signal is input from the reset terminal which is one of external ports of the semiconductor integrated circuit apparatus, and, when the reset signal is released (Step S501), the protect processing control circuit 32 is activated (Step S502).

The protect processing control circuit 32 outputs a signal to the address generation circuit 33 and the read signal generation circuit 34 to cause the address generation circuit 33 and the read signal generation circuit 34 to operate (Step S503).

The protect processing control circuit 32 then reads out data stored in the key code area KA of the memory mat 7a (Step S504) to store the data in the address/key code storage register 35 (Step S505).

The protect processing control circuit 32 judges whether or not a key code (first setting value) is stored in the address/key code storage register 35 (Step S506), and, when the key code is stored, the protect processing control circuit 32 reads out a start address and an end address of the protect area PA from the memory mat 7a to store the addresses in the address/key code storage register 35 (Steps S507 and S508).

After completion of the processing of Step S508 or when there is no key code in the processing of Step S506, a release signal for releasing the internal reset of the semiconductor integrated circuit apparatus is output (Step S509), and then the protect processing control circuit 32 is stopped (Step S510) to cause the semiconductor integrated circuit apparatus 1 to start operation.

The key code reading, the key code setting for the control circuit 7b, and the check for protect on the protect area are executed in accordance with the above-described flow after the release of reset. After the semiconductor integrated circuit apparatus 1 starts normal operation, a control based on a memory access address in accordance with FIG. 4 is executed.

In the case where each of the protect area PA and the protect area PA1 is a fixed area, steps S507 and S508 are not executed.

FIG. 16 is a flowchart indicating an arbitrary setting processing of the protect area PA in the flash memory 7, and FIG. 17 is a diagram for supplementary illustrating a memory map of the flash memory 7 in FIG. 16.

To start with, debugging of a program is started (Step S601), and program writing and erasure (Step S602) are performed until completion of the debugging (Step S603). After the completion of debugging, an arbitrary start address of the protect area PA is written in the start address storage area SDA provided in the memory mat 7a, and an arbitrary end address of the protect area PA is written in the end address storage area MDA, so that an arbitrary area of the protect area PA is set and a key code is written in the key code area KA (Step 604).

In this case, by setting the start address and the end address in the start address storage area SDA and the end address storage area MDA in such a fashion that the key code area KA is in the protect area PA, it is possible to prevent alteration and readout of the protect area or readout or alteration of the key code by a third party.

According to the second embodiment, since the area of the protect area PA is arbitrarily changed, it is possible to perform flexible changes in accordance with a data capacity of a program of which reading/writing is to be prohibited, and it is possible to prevent a third party from reading out, copying or altering the program.

Though the invention achieved by the present inventor has been described based on the embodiments in the foregoing, this invention is not limited to the foregoing embodiments, and various modifications are possible insofar as the modifications do not depart from the scope of this invention.

### INDUSTRIAL APPLICABILITY

The semiconductor integrated circuit apparatus of this invention is applicable to technologies for prevention of reading and rewriting of a predetermined block in a nonvolatile semiconductor memory.

1. A semiconductor integrated circuit apparatus comprising:
a nonvolatile storage provided with a memory array unit having a plurality of nonvolatile memory cells and a control unit for controlling write operation of storing information in the nonvolatile memory cells, read operation of reading out the information stored in the nonvolatile memory cells, and erase operation of erasing the information stored in the nonvolatile memory cells;
a volatile storage to be used as a work area of a program stored in the nonvolatile storage;
a central processing unit capable of executing a predetermined processing and giving instructions to the nonvolatile storage; and
a protect operation control unit for controlling the nonvolatile storage and the read operation of the nonvolatile storage, wherein
the memory array unit has a first protect memory area in which reading and writing of information stored are prohibited under the control of the protect operation control unit;
the volatile storage has a second protect memory area in which reading from an area other than the first protect memory area of the memory array unit is prohibited under the control of the protect operation control unit; and
the second protect memory area of the volatile storage is used as a work area of a program stored in the first protect memory area of the nonvolatile storage.

2. A semiconductor integrated circuit apparatus comprising:
a nonvolatile storage provided with a memory array unit having a plurality of nonvolatile memory cells and a control unit for controlling write operation of storing information in the nonvolatile memory cells, read operation of reading out the information stored in the nonvolatile memory cells, and erase operation of erasing the information stored in the nonvolatile memory cells;
a volatile storage;
a central processing unit capable of executing a predetermined processing and giving instructions to the nonvolatile storage; and
a protect operation control unit for controlling the nonvolatile storage and the read operation of the nonvolatile storage, wherein
the memory array unit has a first protect memory area in which reading and writing of information stored are prohibited under the control of the protect operation control unit; and
the volatile storage has a second protect memory area in which reading and writing from an area other than the first protect memory area of the memory array unit are prohibited under the control of the protect operation control unit.

3. The semiconductor integrated circuit apparatus according to claim 1, wherein
the protect operation control unit compares an address signal output from the central processing unit with a value of a program counter to judge whether or not the address signal is inside the first protect memory area.

4. The semiconductor integrated circuit apparatus according to claim 3, wherein
the protect operation control unit compares an address signal output from the central processing unit with a value of a program counter to permit reading in the first protect memory area only in the case where the address signal and the program counter value are address values inside the first protect memory area.

5. The semiconductor integrated circuit apparatus according to claim 1, wherein
the protect operation control unit compares an address signal output from the central processing unit with a value of a program counter to judge whether or not the address signal is inside the second protect memory area.

6. The semiconductor integrated circuit apparatus according to claim 5, wherein
the protect operation control unit compares an address signal output from the central processing unit with a value of a program counter to permit reading in the second protect memory area only in the case where the program counter value is inside the first protect memory area and the address signal is an address value inside the second protect memory area.

7. The semiconductor integrated circuit apparatus according to claim 1, further comprising an erasure prohibition control unit for prohibiting erasure in the first protect memory area.

8. The semiconductor integrated circuit apparatus according to claim 7, wherein
the erasure prohibition control unit is provided with
a key code generation circuit for outputting a previously set key code signal and
an erasure control circuit for prohibiting erasure in the first protect memory area when a key code signal generated by the key code generation circuit compares and coincides with a key code stored in the first protect memory area in the case where erasure operation of the memory array unit occurs.

9. The semiconductor integrated circuit apparatus according to claim 1, further comprising an rewrite prohibition control unit for prohibiting rewrite in the first protect memory area.

10. The semiconductor integrated circuit apparatus according to claim 9, wherein
the rewrite prohibition control unit is provided with:
a key code generation circuit for outputting a previously set key code signal;
an address judgment unit for judging whether or not the rewrite destination address signal is in the first protect memory area;
a key code judgment unit for comparing a key code signal generated by the key code generation circuit and a key code stored in the first protect memory area and outputting a coincidence signal when the key codes coincide with each other; and
a rewrite control circuit for outputting a rewrite prohibition signal for prohibiting rewrite in the first protect memory area in the case where the rewrite destination address signal is in the first protect memory area and the key codes coincide with each other when rewrite operation of the memory array unit occurs.

11. An electric system comprising:
a nonvolatile semiconductor storage apparatus provided with a nonvolatile storage provided with a memory array unit having a plurality of nonvolatile memory cells and a control unit for controlling write operation of storing information in the nonvolatile memory cells, read operation of reading out the information stored in the nonvolatile memory cells, and erase operation of erasing the information stored in the nonvolatile memory cells;
a volatile semiconductor storage apparatus to be used as a work area of a program stored in the nonvolatile semiconductor storage apparatus;
a semiconductor integrated circuit apparatus provided with a central processing unit capable of executing a predetermined processing and giving instructions to the nonvolatile semiconductor storage apparatus and a protect operation control unit for controlling the nonvolatile semiconductor storage apparatus and the read operation of the volatile semiconductor storage apparatus, wherein
the memory array unit has a first protect memory area in which reading of information stored is prohibited under the control of the protect operation control unit;
the volatile semiconductor storage apparatus has a second protect memory area in which reading from an area other than the first protect memory area of the memory array unit is prohibited under the control of the protect operation control unit; and
the second protect memory area is used as a work area of a program stored in the nonvolatile semiconductor storage apparatus.

12. The electric system according to claim 11, wherein
the protect operation control unit compares an address signal output from the central processing unit with a value of a program counter to judge whether or not the address signal is inside the first and the second protect memory areas.

13. The electric system according to claim 12, wherein
the protect operation control unit compares an address signal output from the central processing unit with a value of a program counter to permit reading in the first protect memory area in the case where the address signal and the program counter value are address values inside the first protect memory area and to permit reading in the second protect memory area in the case where the address signal is an address value inside the second protect memory area.

14. The electric system according to claim 11, further comprising an erasure prohibition control unit for prohibiting erasure in the first protect memory area.

15. The electric system according to claim 11, further comprising a rewrite prohibition control unit for prohibiting rewrite in the first protect memory area.

16. The semiconductor integrated circuit apparatus according to claim 2, wherein
the protect operation control unit compares an address signal output from the central processing unit with a value of a program counter to judge whether or not the address signal is inside the first protect memory area.

17. The semiconductor integrated circuit apparatus according to claim 16, wherein
the protect operation control unit compares an address signal output from the central processing unit with a value of a program counter to permit reading in the first protect memory area only in the case where the address signal and the program counter value are address values inside the first protect memory area.

18. The semiconductor integrated circuit apparatus according to claim 2, wherein
the protect operation control unit compares an address signal output from the central processing unit with a value of a program counter to judge whether or not the address signal is inside the second protect memory area.

19. The semiconductor integrated circuit apparatus according to claim 18, wherein
the protect operation control unit compares an address signal output from the central processing unit with a value of a program counter to permit reading in the second protect memory area only in the case where the program counter value is inside the first protect memory area and the address signal is an address value inside the second protect memory area.

20. The semiconductor integrated circuit apparatus according to claim 2, further comprising an erasure prohibition control unit for prohibiting erasure in the first protect memory area.

21. The semiconductor integrated circuit apparatus according to claim 20, wherein
the erasure prohibition control unit is provided with
a key code generation circuit for outputting a previously set key code signal and
an erasure control circuit for prohibiting erasure in the first protect memory area when a key code signal generated by the key code generation circuit compares and coincides with a key code stored in the first protect memory area in the case where erasure operation of the memory array unit occurs.

22. The semiconductor integrated circuit apparatus according to claim 2, further comprising an rewrite prohibition control unit for prohibiting rewrite in the first protect memory area.

23. The semiconductor integrated circuit apparatus according to claim 22, wherein
the rewrite prohibition control unit is provided with:
a key code generation circuit for outputting a previously set key code signal;
an address judgment unit for judging whether or not the rewrite destination address signal is in the first protect memory area;
a key code judgment unit for comparing a key code signal generated by the key code generation circuit and a key code stored in the first protect memory area and outputting a coincidence signal when the key codes coincide with each other; and
a rewrite control circuit for outputting a rewrite prohibition signal for prohibiting rewrite in the first protect memory area in the case where the rewrite destination address signal is in the first protect memory area and the key codes coincide with each other when rewrite operation of the memory array unit occurs.
